(19) United States
(12) Patent Application Publication
(10) Pub. No.: US 2018/0233651 A1
(43) Pub. Date: Aug. 16, 2018

(54) PIEZOELECTRIC SENSOR MANUFACTURING METHOD AND PIEZOELECTRIC SENSOR USING THE SAME

(71) Applicant: BEFS CO., LTD., Seoul (KR)

(72) Inventor: Changhyeok BANG, Seoul (KR)

(21) Appl. No.: 15/897,676

(22) Filed: Feb. 15, 2018

(30) Foreign Application Priority Data
Feb. 16, 2017 (KR) 10-2017-0021088

(51) Int. Cl. H01L 41/047; H01L 41/113; H01L 41/333; H01L 41/332; H01L 41/29

(52) U.S. Cl. CPC H01L 41/047; H01L 41/1132; G01B 17/06; H01L 41/332; H01L 41/29; H01L 41/333

(57) ABSTRACT

A piezoelectric sensor manufacturing method according to the present invention comprises the steps of: forming a mold in the form of a sensor array pattern including a plurality of grooves by etching a base substrate; injecting a piezoelectric material in inner grooves among the plurality of grooves and injecting a conductive material in outer grooves; sintering the injected piezoelectric material and conductive material; forming piezoelectric rods and conductive rods by etching the base substrate to protrude the piezoelectric material and the conductive material; forming an insulation layer by filling an insulation material in the base substrate; flattening the insulation layer until the piezoelectric rods and the conductive rods are exposed; forming a first electrode on a first surface of the piezoelectric material and the conductive material; bonding a dummy substrate on the base substrate on which the first electrode is formed; flattening the base substrate until the piezoelectric rods and the conductive rods are exposed; and forming a second electrode on a second surface of the piezoelectric rods and the conductive rods.

### CROSS REFERENCE TO RELATED APPLICATION

The present application claims the benefit of Korean Patent Application No. 10-2017-0021088 filed in the Korean Intellectual Property Office on Feb. 16, 2017, the entire contents of which are incorporated herein by reference.

### BACKGROUND OF THE INVENTION

### Field of the Invention

The present invention relates to a piezoelectric sensor manufacturing method and a piezoelectric sensor using the same, and more specifically, to a piezoelectric sensor manufacturing method which can easily apply electrodes by exposing a lower electrode and an upper electrode in the same direction, and a piezoelectric sensor manufactured using the same.

### Background of the Related Art

User authentication is a procedure absolutely necessary in all financial transactions, and particularly, as the interest in mobile financing increases recently owing to development of networks and portable terminals, demands on rapid and accurate authentication apparatuses and authentication methods also increase.

Meanwhile, fingerprints of a user are one of authentication media which can meet the demands described above, and many companies and developers continuously develop apparatuses and methods for authenticating a user by utilizing fingerprints of a user.

Recently, in relation to fingerprint recognition apparatuses, studies on the method of grasping the forms of a fingerprint by generating ultrasonic waves, i.e., a so-called ultrasonic method, are actively progressed, getting out of a method of authenticating images of a fingerprint in a conventional optical method.

Particularly, as security of ultrasonic piezoelectric sensors is further strengthened compared with existing optical or capacitive methods, many studies on the sensors are progressed.

If a voltage is applied to a piezoelectric material, the piezoelectric material vibrates as ultrasonic waves are generated, and the ultrasonic piezoelectric sensor senses a fingerprint.

In an existing piezoelectric sensor having two electrodes needed for application of power, one of the electrodes is formed on the top of the piezoelectric sensor, and the other is formed on the bottom of the piezoelectric element. That is, the piezoelectric element includes an upper electrode and a lower electrode. Conventionally, there are many difficulties in applying voltage as the two electrodes are formed in different direction like this.

### SUMMARY OF THE INVENTION

An object of the present invention is to provide a piezoelectric sensor manufacturing method, which can arrange an upper electrode and a lower electrode on the same plane, and a piezoelectric sensor using the same.

The piezoelectric sensor manufacturing method according to an embodiment of the present invention may include the steps of: forming a mold in the form of a sensor array pattern including a plurality of grooves by etching a base substrate; injecting a piezoelectric material in inner grooves among the plurality of grooves and injecting a conductive material in outer grooves; sintering the injected piezoelectric material and conductive material; forming piezoelectric rods and conductive rods by etching the base substrate to protrude the piezoelectric material and the conductive material; forming an insulation layer by filling an insulation material in the base substrate; flattening the insulation layer until the piezoelectric rods and the conductive rods are exposed; forming a first electrode on a first surface of the piezoelectric material and the conductive material; bonding a dummy substrate on the base substrate on which the first electrode is formed; flattening the base substrate until the piezoelectric rods and the conductive rods are exposed; and forming a second electrode on a second surface of the piezoelectric rods and the conductive rods.

In addition, in the piezoelectric sensor manufacturing method according to an embodiment of the present invention, the step of forming a mold in the form of a sensor array pattern including a plurality of grooves by etching a base substrate may include the step of further forming a hole for forming a poling electrode in a predetermined area of the base substrate.

In addition, in the piezoelectric sensor manufacturing method according to an embodiment of the present invention, the step of injecting a piezoelectric material in inner grooves among the plurality of grooves and injecting a conductive material in outer grooves may include the step of injecting a conductive material for poling in the hole for forming a poling electrode.

In addition, in the piezoelectric sensor manufacturing method according to an embodiment of the present invention, the step of forming a first electrode may include the steps of: depositing a metal layer on the piezoelectric rods and the conductive rods; applying photoresist on the metal layer; removing part of the photoresist by exposing to light according to a mask pattern; etching the metal layer of the part from which the photoresist is removed; and removing remaining photoresist after etching the metal layer.

In addition, in the piezoelectric sensor manufacturing method according to an embodiment of the present invention, the step of forming a first electrode may include the step of forming a first poling electrode by depositing a metal layer on the conductive material for poling and connecting the first poling electrode and the first electrode in one piece.

In addition, in the piezoelectric sensor manufacturing method according to an embodiment of the present invention, the step of forming a second electrode may include the step of forming a second poling electrode in a predetermined area of a second surface of the insulation layer.

In addition, in the piezoelectric sensor manufacturing method according to an embodiment of the present invention, the second electrode may be formed to be connected to the second poling electrode in one piece.

In addition, in the piezoelectric sensor manufacturing method according to an embodiment of the present invention, the second electrode may be formed to separate the metal layer formed on the piezoelectric rods and the metal layer formed on the conductive rods.

In addition, the piezoelectric sensor manufacturing method according to an embodiment of the present invention may further include a poling step of activating the piezoelectric material by applying poling voltage to the first electrode and the second electrode.

In addition, in the piezoelectric sensor manufacturing method according to an embodiment of the present invention, the second electrode may be formed to cross the first electrode in a perpendicular direction.

In addition, in the piezoelectric sensor manufacturing method according to an embodiment of the present invention, the step of forming a second electrode may include the steps of: depositing a metal layer on the piezoelectric rods and the conductive rods; applying photoresist on the metal layer; removing part of the photoresist by exposing to light according to a mask pattern; etching the metal layer of the part from which the photoresist is removed; and removing remaining photoresist after etching the metal layer.

In addition, in the piezoelectric sensor manufacturing method according to an embodiment of the present invention, the step of forming grooves may include the steps of: forming a pattern of a sensor array form on a first surface of the base substrate through a photolithography process; removing the photoresist formed on the base substrate and depositing an insulation layer; and forming the grooves at regular intervals on the base substrate by etching the area from which the photoresist is removed.

In addition, in the sintering step of the piezoelectric sensor manufacturing method according to an embodiment of the present invention, the injected piezoelectric material and conductive material may be sintered at a low temperature for a first period and sintered at a high temperature for a second period.

In addition, in the piezoelectric sensor manufacturing method according to an embodiment of the present invention, the low temperature may be 450 to 550° C.

In addition, in the piezoelectric sensor manufacturing method according to an embodiment of the present invention, the high temperature may be 1050 to 1300° C.

In addition, in the piezoelectric sensor manufacturing method according to an embodiment of the present invention, the conductive material may include any one of a carbon composite, a chopped carbon fiber, an isotropic graphite material, a polyimide composite material power and a rayon-based carbon fiber.

In addition, the piezoelectric sensor according to an embodiment of the present invention may include: a lower electrode; piezoelectric rods formed on the lower electrode; conductive rods formed at one side of the piezoelectric rod; and an upper electrode arranged to cross the lower electrode formed on the piezoelectric rods, wherein power may be applied to the lower electrode through the conductive rods.

### BRIEF DESCRIPTION OF THE DRAWINGS

FIG. 1 is a flowchart illustrating a piezoelectric sensor manufacturing method according to the present invention.

FIG. 2 is a flowchart illustrating a mold forming step in detail.

FIG. 3 is a perspective view showing the base substrate 10 in a state of completing up to the etching process.

FIG. 4 is a view showing the injection step in detail in the step of injecting and sintering a piezoelectric material (step S11).

FIG. 5 is a perspective view showing the base substrate 10 in a state of completing injection of a piezoelectric material 18 and a conductive material 19.

FIG. 6 is a view showing the base substrate 10 flattened through a CMP process.

FIG. 7 is a perspective view showing the base substrate in a state of completing the etching process (step S12) in the method as described above.

FIG. 8 is a view showing the base substrate in a state of applying an insulation layer 23.

FIG. 9 is a view showing a state of cutting off the top portion of the insulation layer 23 through a CMP process.

FIG. 10 is a view showing a first electrode forming step (step S14) in detail.

FIG. 11 is a perspective view showing the base substrate 10 in a state of completing formation of the first electrode 26.

FIG. 12 is a perspective view showing a state of bonding a dummy substrate 28.

FIG. 13 is a view showing a state of completing the CMP process on the base substrate 10.

FIG. 14 is a cross-sectional view showing the electrodes attached on the dummy substrate.

FIG. 15 is a perspective view showing a dummy substrate 28 in a state of completing formation of a second electrode.

FIG. 16 is a view showing the configuration of applying poling voltage.

FIG. 17 is a view showing a piezoelectric sensor completed after a dicing process.

DESCRIPTION OF SYMBOLS

| | |
|---|---|
| 10: base substrate | 11: photoresist |
| 12: mask pattern | 14: groove |
| 16: insulation film | 18: piezoelectric material |
| 19: conductive material | 20: piezoelectric rod |
| 21, 22: conductive rod | 23: sensor array pattern |
| 23: insulation layer | 24: metal layer |
| 25: photoresist | 26: first electrode |
| 27: first poling electrode | 28: dummy substrate |
| 30: second electrode | 31: second poling electrode |

### DETAILED DESCRIPTION OF THE PREFERRED EMBODIMENT

Details of the objects and technical configuration of the present invention described above and operational effects according thereto will be further clearly understood hereinafter by the detailed description with reference to the accompanying drawings attached in the specification of the present invention. The embodiments according to the present invention will be described in detail with reference to the accompanying drawings.

The embodiments disclosed in this specification should not be interpreted or used to limit the scope of the present invention. It is natural to those skilled in the art that the description including the embodiments of the specification has various applications. Accordingly, the arbitrary embodiments disclosed in the detailed description of the present invention are for illustrative purposes and do not intend to limit the scope of the present invention to the embodiments.

The functional blocks shown in the figures and described below are merely examples of possible implementations. In other implements, other functional blocks may be used without departing from the spirit and scope of the detailed description. In addition, although one or more functional blocks of the present invention are expressed as individual blocks, one or more of the functional blocks may be a combination of various hardware and software configurations executing the same function.

In addition, the expression of ‘including’ a constitutional sensor is an expression of an ‘open type’ which merely refers to existence of a corresponding constitutional sensor, and it should not be construed as precluding additional constitutional sensors.

Furthermore, it will be understood that when a constitutional sensor is referred to as being ‘connected’ or ‘coupled’ to another constitutional sensor, it may be directly connected or coupled to the other constitutional sensor or intervening sensors may be present.

The expressions such as ‘first’ and ‘second’ are expressions used only to distinguish a plurality of configurations and do not limit the sequence or other features of the configurations.

When an element is connected to another element, it includes a case of indirectly connecting the elements with intervention of another element therebetween, as well as a case of directly connecting the elements. In addition, the concept of including a constitutional sensor means further including another constitutional sensor, not excluding another constitutional sensor, as far as an opposed description is not specially specified.

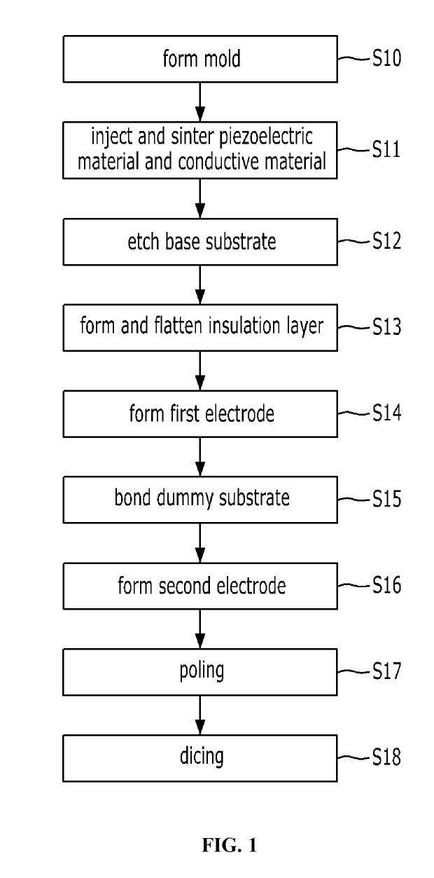

FIG. 1 is a flowchart illustrating a piezoelectric sensor manufacturing method according to the present invention.

Referring to FIG. 1, a piezoelectric sensor manufacturing method includes a mold forming step (step S10), a piezoelectric material and conductive material injecting and sintering step (step S11), a base substrate etching step (step S12), an insulation layer forming and flattening step (step S13), a first electrode forming step (step S14), a dummy substrate bonding step (step S15), a second electrode forming step (step S16), a poling step (step S17) and a dicing step (step S18).

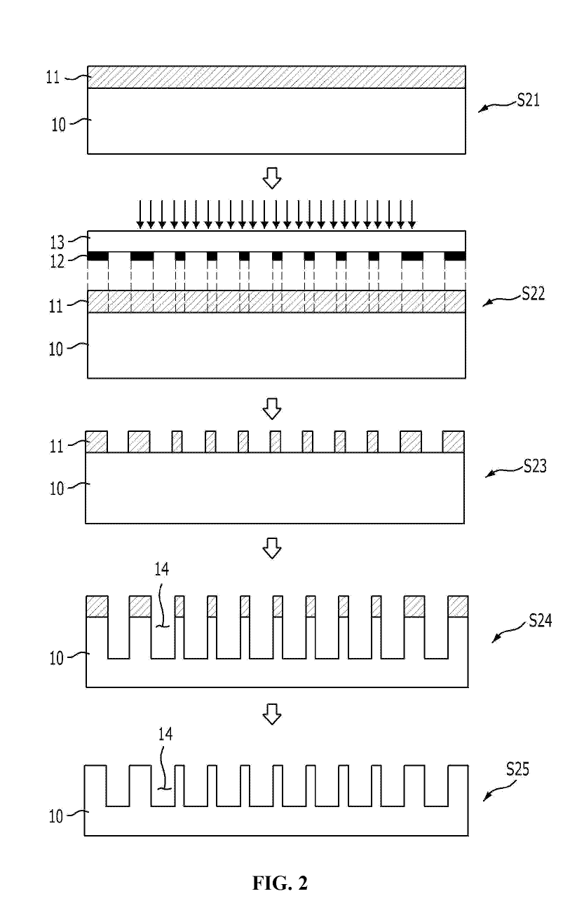

Describing each of the steps in further detail, the mold forming step (step S10) may include the steps shown in FIG. 2.

A mold can be formed using a photolithography process. The photolithography is a technique of copying a desired circuit design by transferring a shadow generated by radiating light on an original plate, i.e., a mask in which the desired circuit design is formed on a glass plate as a metal pattern, on a wafer, and it is the most important process in forming a designed pattern on a wafer in the process of manufacturing a semiconductor. More specifically, the mold forming step includes: a coating process of uniformly applying a photoresist composition on the surface of a wafer; a soft baking process of attaching a photoresist film on the surface of the wafer by evaporating solvent from the applied photoresist film; a light exposure process of transferring a pattern of a mask on the photoresist film by exposing the photoresist film to light while repeatedly and sequentially projecting the circuit pattern on the mask to be reduced using a light source such as an ultraviolet ray or the like; a development process of selectively removing the portions having different physical properties, such as difference of solubility according to light sensing of exposure to the light source, using a developer; a hard baking process of further tightly adhering the photoresist film remaining on the wafer after the development process to the wafer; an etching process of etching predetermined portions according to the pattern of the developed photoresist film; and a strip process of removing unnecessary photoresist films after the above processes. A medium is needed to transfer the circuit design of the original plate of the mask to the wafer through the light exposure process since the properties of the materials used for a semiconductor element are not changed although the materials are exposed to light, and the medium is referred to as photoresist. The photoresist refers to a material which can selectively remove a portion exposed to light or a portion not exposed to light in the following development process using the characteristic such as the photoresist receives light of a specific wavelength and its solubility is changed in the developer. Generally, the photoresist selectively removes a portion changed by light using a developer, and if a portion receiving the light is melted well by the developer, it is referred to as positive resist, or otherwise, it is referred to as negative resist.

Referring to FIG. 2, first, photoresist is deposited on a prepared base substrate 10 (step S21). The base substrate is a semiconductor substrate, and although it may be a silicon single crystal substrate, it also can be a silicon-on-insulator (SOI) substrate, a germanium (Ge) substrate, a gallium phosphide (GaP) substrate, a gallium arsenide (GaAs) substrate or the like, and it is not specially limited. In addition, a circular silicon wafer can be used as the base substrate 10. In addition, the photoresist 11 is a photoresist material, and a material having a chemical characteristic changed by radiating light of a predetermined wavelength may be appropriately selected and used, and it is not specially limited. The method of forming the photoresist 11 on the base substrate 10 may be, for example, a spin coating method, a spray coating method or a dip coating method, and it is not limited thereto. Selectively, a bake referred to as a so-called post applied bake (PAB) may be performed after the photoresist 11 is formed in a method such as spin coating or the like. Some of the solvent in the photoresist 11 is removed through the bake, and the photoresist 11 is stably deposited on the base substrate 10.

Next, the photoresist is removed according to the pattern through the light exposure and development processes. That is, the photoresist of an area in which the mask pattern 12 does not exist is removed by arranging a glass substrate 13 attached with a mask pattern 12 of a shape desired to manufacture on the base substrate 10 and exposing the photoresist 11 to light (step S22).

The photoresist in the portions exposed to light is removed through the light exposure and development processes, and the portions not exposed to light remain on the substrate (step S23).

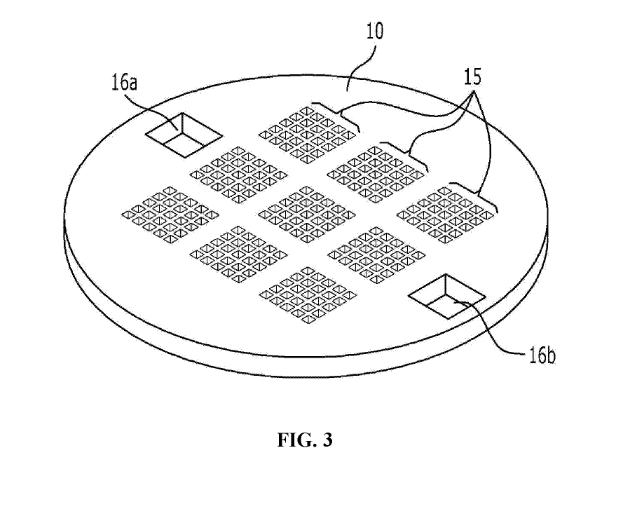

If the photoresist 11 is removed, a plurality of grooves is formed by etching the base substrate 10 of the areas from which the photoresist is removed (step S24). Both side portions of the plurality of grooves 14 are portions in which a conductive material is injected, and the other portions are portions in which a piezoelectric material is injected. The both side portions are portions for forming electrodes, and the inner portions are portions for forming cells of the piezoelectric sensor. Although not shown in the figure, holes (16a and 16b of FIG. 3) for forming poling electrodes may be formed in predetermined areas of the base substrate 10, in which the piezoelectric sensor array is not formed. A conductive material may be injected in the holes for forming the poling electrodes. Injection of the conductive material and the piezoelectric material will be described below.

The etching process of etching the base substrate 10 may be divided into dry etching and wet etching. The wet etching is a method of removing part of the base substrate 10 by generating a chemical reaction with the surface of the base substrate 10 using a chemical solution. Since the wet etching is generally isotropic etching, it generates an undercut and is difficult to form an accurate pattern. In addition, it is disadvantageous in that the process control is difficult, the etchable line width is limited, and a problem of processing additionally generated etching solution occurs. Accordingly, the dry etching capable of compensating for the disadvantages of the wet etching is used more frequently. The dry etching is a process of forming plasma by applying power after injecting reaction gas into a vacuum chamber, and removing part of the base substrate 10 by chemically or physically reacting the plasma with the surface of the base substrate 10. In this embodiment, the dry etching which can easily control the process, perform antisotropic etching and form an accurate pattern may be used. Particularly, deep reactive ion etching (DRIE), which is physical etching included in the dry etching, may be used. The DRIE process generates plasma by dissociating gas using an energy source after injecting reactive gas into a vacuum chamber. The etching is accomplished through sputtering by accelerating ions generated in the plasma in the electric field and colliding the ions on the surface of the base substrate 10.

If the etching the base substrate 10 is completed, formation of a mold is completed by completely removing the remaining photoresist 11 (step S25). At this point, the photoresist 11 can be removed in a chemical method or using the plasma.

FIG. 3 is a perspective view showing the base substrate 10 in a state of completing up to the etching process.

Referring to FIG. 3, it may be confirmed that a plurality of sensor array patterns 15 is formed on the base substrate 10 by etching. In addition, the holes 16a and 16b formed by etching in the edge areas of the base substrate 10 are areas for applying a poling electrode. The holes 16a and 16b for forming the poling electrodes may be formed in any area on the base substrate 10 if the sensor array patterns 15 are not formed. In addition, although a case of forming two holes 16a and 16b is shown in this embodiment, only one hole can be formed.

If formation of the mold is completed, a piezoelectric material and a conductive material are injected into the holes and sintered (step S11).

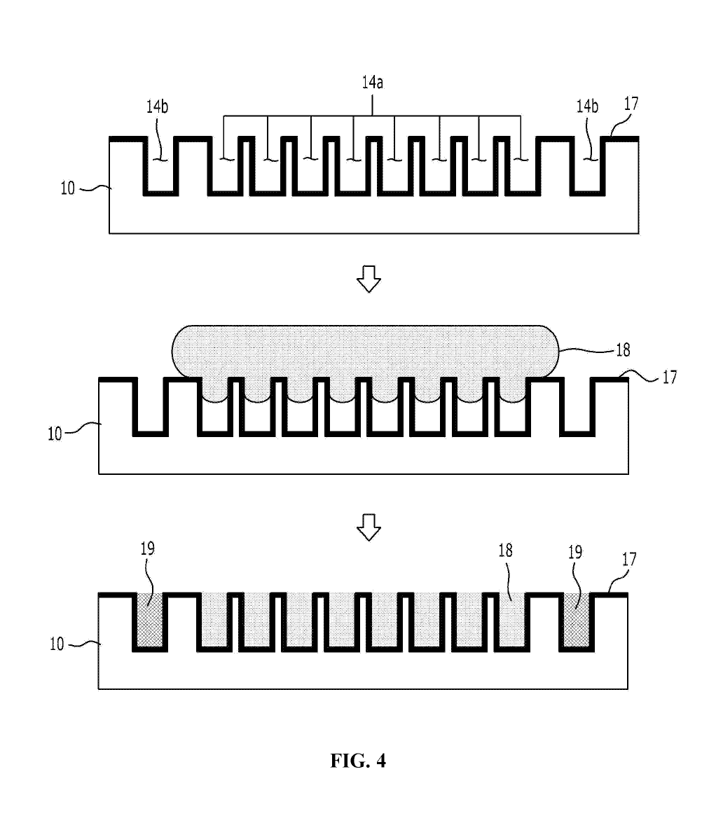

FIG. 4 is a view showing the injection step in detail in the step of injecting and sintering a piezoelectric material (step S11).

Referring to FIG. 4, after depositing an insulation film 17 on the base substrate 10, a piezoelectric material 18 is injected into the grooves 14a formed on the inner side among the plurality of grooves 14. Silicon dioxide (SiO2), silicon nitride (SiNx), aluminum oxide (Al₂O₃) or the like may be used as a material of the insulation film 17. The insulation film 17 may be deposited using a Physical Vapor Deposition (PVD) method or a Chemical Vapor Deposition (CVD) method as the method of depositing the insulation film. Meanwhile, examples of the PVD method may be a sputtering method and an e-beam evaporation method.

In addition, lead zirconate titanate (PZT) may be used as the piezoelectric material 18, and the piezoelectric material 18 may be further transparent by adding lanthanum (La). As a method of injecting the piezoelectric material, a powder type piezoelectric material is injected as shown in the figure, and the piezoelectric material may be injected by adding pressure from the top using a flat pressing plate not to have a crack in the etched portions. At this point, the piezoelectric material may be injected using hot embossing equipment like HEX 04 of Jenoptik Co.

In addition, a conductive material may be injected in the groove 14b formed on the outer side among the plurality of grooves. The conductive material may be injected in a method the same as the method of injecting the piezoelectric material.

A material having high thermal resistance may be used as the conductive material. It is since that the piezoelectric material should go through a sintering process at a high temperature to operate as a piezoelectric sensor. A kind of carbon composite or a chopped carbon fiber may be used as a conductive material of high thermal resistance.

In addition, a special graphite such as an isotropic graphite material, a polyimide composite material power or a rayon-based carbon fiber may be used as a conductive material of high thermal resistance.

Other than these, various kinds of conductive materials capable of maintaining conductivity may be used also in the sintering process.

Although a case of injecting the piezoelectric material 18 first and then injecting the conductive material 19 is shown in this embodiment, the order of injection is not important. That is, the conductive material 19 may be injected first, or both of the materials may be injected simultaneously.

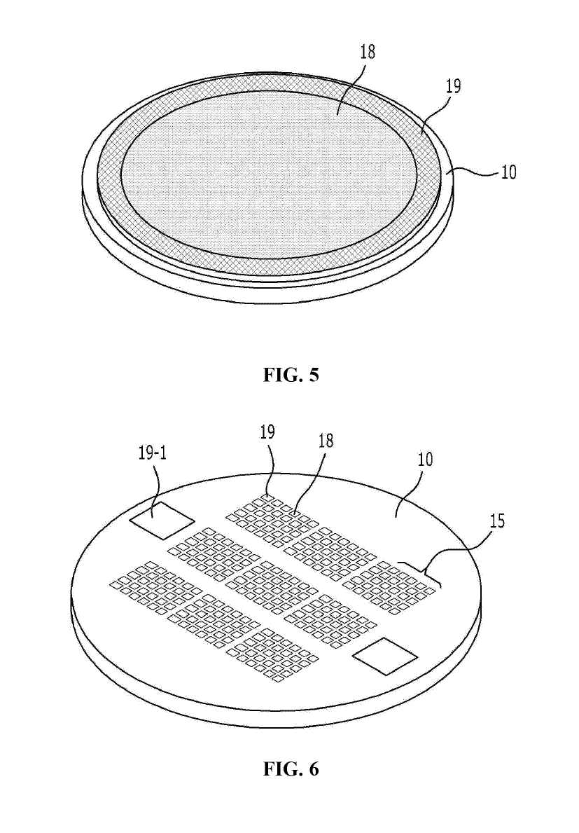

FIG. 5 is a perspective view showing the base substrate 10 in a state of completing injection of a piezoelectric material 18 and a conductive material 19.

It may be confirmed that since the piezoelectric material is injected in the inner grooves 14a among the plurality of grooves, cells are form in the inner area of the base substrate 10, and since the conductive material 19 is injected in the outer grooves 14b, electrodes are formed in the outer area of the base substrate 10.

If injection of the piezoelectric material 18 and the conductive material 19 is completed, the piezoelectric material 18 and the conductive material 19 are sintered (step S11).

As a method of sintering, the piezoelectric material, e.g., a binder, is burnt out by performing a first sintering at a low temperature, and a second sintering is performed at a high temperature. The first sintering is performed approximately at a temperature of 450 to 550° C. for about one hour, and the second sintering is performed approximately at a temperature of 1200 to 1500° C. for about two hours.

If the sintering process is completed as described above, the base substrate is flattened through a Chemical Mechanical Polishing (CMP) process and etched to protrude the sensor array pattern (step S12). That is, the cells of the sensor are formed as PZT rods of a pillar shape.

FIG. 6 is a view showing the base substrate 10 flattened through a CMP process.

Referring to FIG. 6, a plurality of sensor array patterns 15 is formed of piezoelectric materials 18, and a conductive material 19 are formed at one side of each sensor array pattern 15. In addition, an area 19-1 filled with a conductive material is formed in a predetermined edge area of the base substrate 10. Although it is shown in this embodiment that the piezoelectric rod 18 is formed in a rectangular shape, it may be formed in a circular shape and may be implemented in various shapes.

In addition, in the etching process, a mask is formed in a specific area of the base substrate not to etch a corresponding portion. The dry etching (DRIE) process may be used in the etching process as described above.

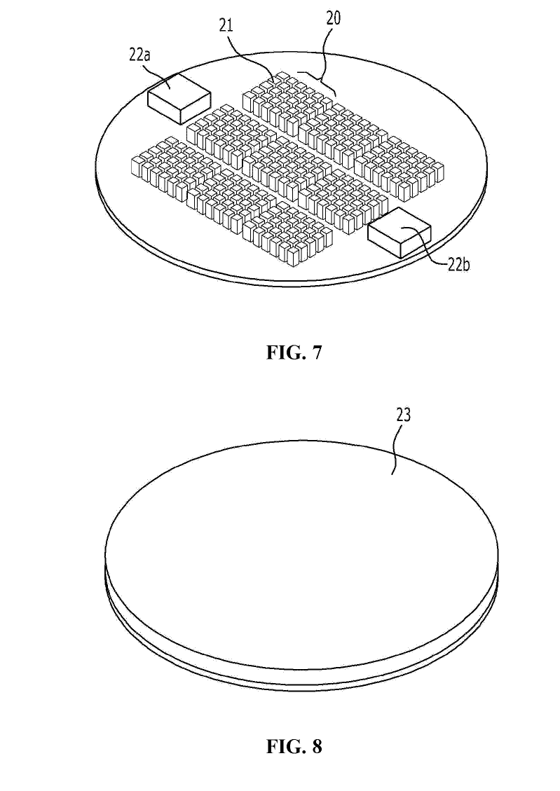

FIG. 7 is a perspective view showing the base substrate in a state of completing the etching process (step S12) in the method as described above.

Referring to FIG. 7, the base substrate 10 includes a plurality of piezoelectric rods 20, a first conductive rod 21 formed at one side of the piezoelectric rods 20, and a second conductive rod 22 formed in a predetermined edge area of the base substrate 10. The plurality of piezoelectric rods 20 is formed in the shape of a sensor array pattern.

The first conductive rod 21 is a portion for applying a first power, and the second conductive rod 22 is a portion for applying a first poling power.

A plurality of sensor array patterns is formed on the base substrate 10, and each array may operate as one ultrasonic sensor. In addition, a plurality of cells is formed in a pillar shape in one ultrasonic sensor. Formation of a poling electrode and a sensor electrode will be described below. Meanwhile, although only one reference numeral is used to denote the first conductive rod 21 for convenience, the same reference numeral may be applied to a plurality of array patterns.

If the semiconductor etching process (step S12) is completed through the process as described above, an insulation layer is formed by injecting an insulation material 23 in the etched portions of the base substrate 10, and the base substrate 10 is flattened (step S13).

A CMP process may be used as a method of cutting off the insulation layer. A material capable of attenuating high frequency ultrasonic signals and implementing electrical insulation may be used as the insulation material to optimize the noise and sensitivity of a signal when the piezoelectric sensor operates. For example, an epoxy maybe used. In addition, a flattening process is performed until the piezoelectric rods and the first and second conductive rods 21 and 22 are exposed.

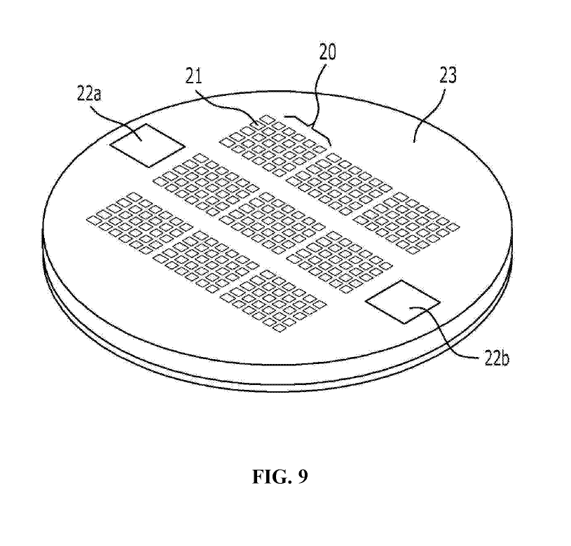

FIG. 8 is a view showing the base substrate in a state of applying an insulation layer 23, and FIG. 9 is a view showing a state of cutting off the top portion of the insulation layer 23 through a CMP process.

Referring to FIG. 9, an insulation material is filled between the piezoelectric rods 20, the first conductive rod 21 and the second conductive rod 22, and only one side is exposed.

If the insulation layer flattening process (step S13) is completed, a first electrode is formed (step S14).

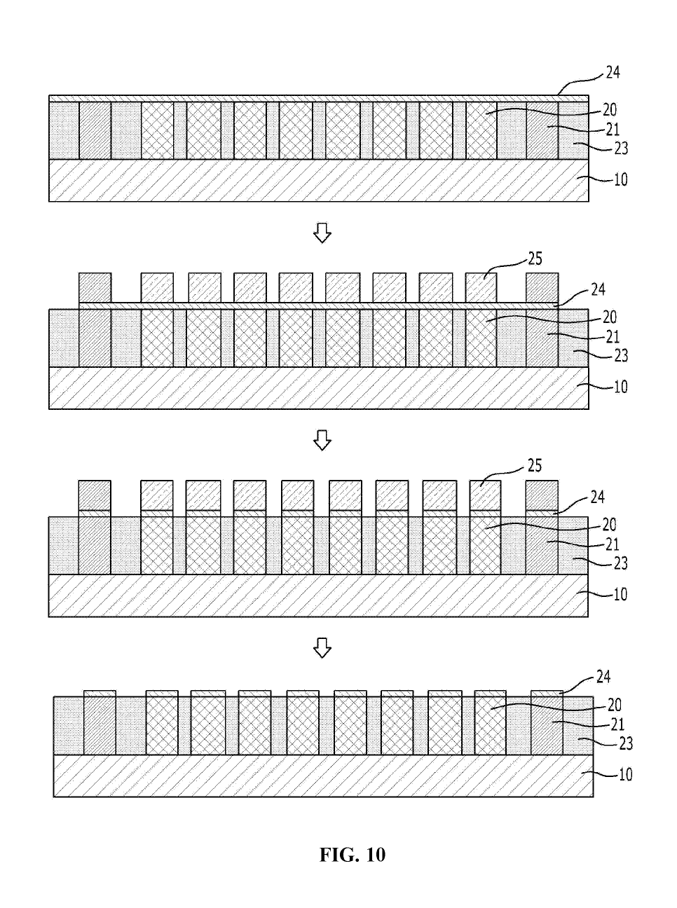

FIG. 10 is a view showing a first electrode forming step (step S14) in detail.

Referring to FIG. 10, first, a metal layer 24 is deposited on the base substrate 10. A sputtering process may be used as the deposition method.

Next, after applying the photoresist 25, part of the photoresist 25 is removed by exposing to light according to a mask pattern, and the metal layer 24 of the part from which the photoresist 25 is removed is etched. At this point, the mask pattern covers all the piezoelectric rods 20 and the conductive rods 21 so that the photoresist of the area in which the rods 20 and 21 are not formed may be removed. Formation of the electrodes is completed by removing all the photoresist remaining after the metal layer is etched. The metal layer 24 finally remaining after the etching process performs the function of the first electrode.

Although not shown in FIG. 10, part of the first electrode may also be formed by depositing the metal layer 24 on the second conductive rod 22. That is, at this point, a poling electrode may be formed in a predetermined edge area of the base substrate 10.

FIG. 11 is a perspective view showing the base substrate 10 in a state of completing formation of the first electrode 26.

The first electrode 26 may be a conductive material such as a metal and may be formed through a print process as needed. Observing the first electrode specifically, the first electrode may include any one material selected from a group of copper, aluminum, gold, silver, nickel, tin, zinc and an alloy of these. This is a material which can substitute for existing indium tin oxide (ITO) and may be formed in a cost-effective and simple process. In addition, since it can demonstrate a further superior electrical conductivity, electrical characteristics can be improved. In addition, the first electrode may include metal oxide such as indium zinc oxide, copper oxide, tin oxide, zinc oxide, titanium oxide or the like. In addition, the first electrode may include a nanowire, a photosensitive nanowire film, a carbon nanotube (CNT), graphene, a conductive polymer or a mixture of these. If a nanocomposite such as a nanowire or a carbon nanotube (CNT) is used, the first electrode may be formed in black color and has an advantage of controlling the color and reflectivity while securing electrical conductivity through the control of nano-powder content. Alternatively, the first electrode may include various metals. For example, the electrode 200 may include at least any one metal among chrome (Cr), copper (Cu), aluminum (Al), silver (Ag), molybdenum (Mo), gold (Au), titanium (Ti) and an alloy of these.

Referring to FIG. 11, it may be confirmed that a plurality of first electrode lines 26 is connected to the first poling electrodes 27a and 27b. Although all the first electrode 26 and the first poling electrodes 27a and 27b are formed by the metal layer 24, different names are assigned according to functions.

Next, a dummy substrate is bonded on the base substrate 10.

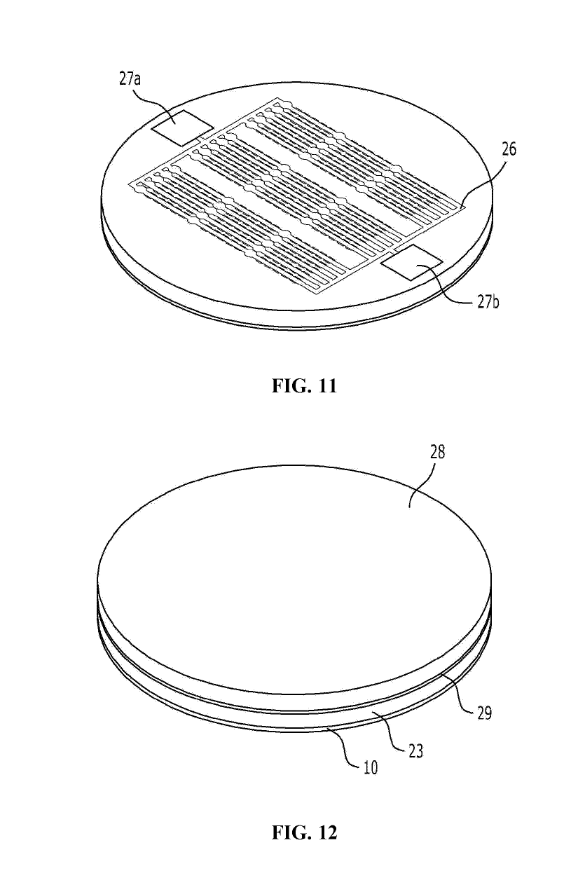

FIG. 12 is a perspective view showing a state of bonding a dummy substrate 28.

After the first electrode is formed, the second electrode should be formed on the opposite side by inverting the base substrate 10. The dummy substrate 28 is needed for the following process. The dummy substrate 28 may be bonded to the insulation layer 23 using an adhesive. Various adhesive materials such as a thermosetting resin, an optical film, an optical resin and the like may be used as the adhesive.

If the dummy substrate 28 is bonded, the substrates are inverted to face the dummy substrate 28 upward and the base substrate 10 downward, and the base substrate 10 is flattened through a CMP process. At this point, the base substrate 10 is flattened until the piezoelectric rods 20 and the conductive rods 21 and 22 are exposed.

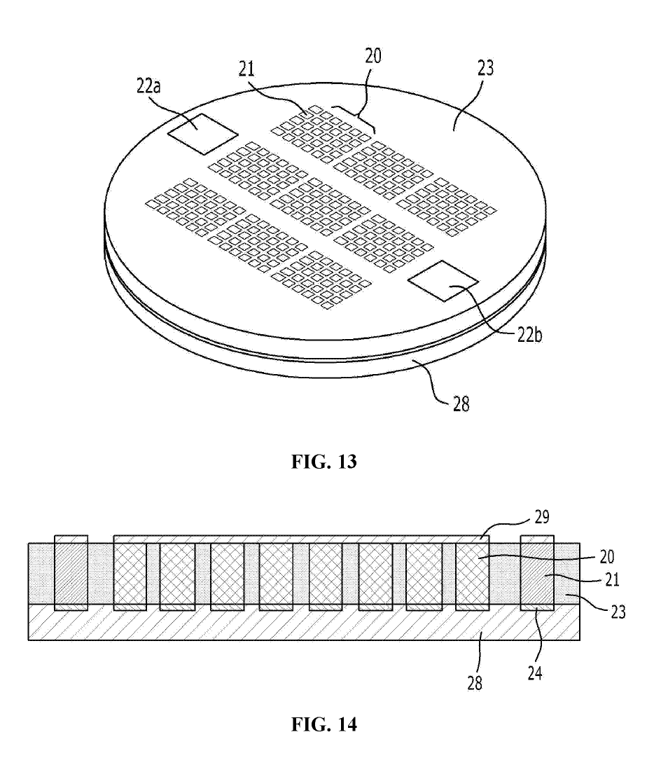

FIG. 13 is a view showing a state of completing the CMP process on the base substrate 10.

Referring to FIG. 13, only the insulation layer 23 is formed on the dummy substrate 28, and the piezoelectric rods 20 and the conductive rods 21 and 22 are formed therebetween.

If the CMP process is completed, a second electrode is formed on the piezoelectric rods and the conductive rods (step S16).

The second electrode may be formed in a method the same as the method of forming the first electrode. That is, as shown in FIG. 10, the second electrode may be formed in a method of depositing a metal layer and patterning and etching the metal layer through a photolithography process. At this point, a metal layer for applying a poling electrode is formed in a predetermined edge area of the insulation layer 23 to be integrated with the second electrode.

FIG. 14 is a cross-sectional view showing the electrodes attached on the dummy substrate.

Referring to FIG. 14, the first metal layer 24 is arranged on the dummy substrate 28, and the piezoelectric rods and the conductive rods 21 are arranged on the first electrode, and the second metal layer 29 is arranged on the piezoelectric rods 20 and the conductive rods 21.

The first metal layer 24 configures the first electrode, and the second metal layer 29 configures the second electrode. The first electrode and the second electrode are arranged to cross each other in a perpendicular direction.

Although the poling electrode is not shown in FIG. 14, the poling electrode part may also be formed by the second metal layer.

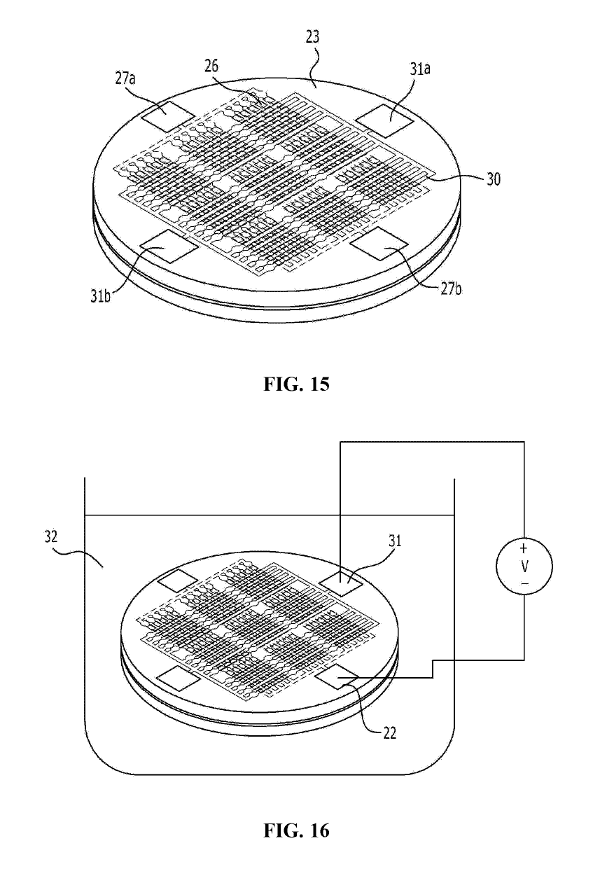

FIG. 15 is a perspective view showing a dummy substrate 28 in a state of completing formation of a second electrode.

Referring to FIG. 15, a plurality of second electrode lines is connected to the second poling electrodes 31a and 31b in one piece. Although the second electrode 30 and the second poling electrodes 31a and 31b are the second metal layer 29, different names are assigned according to functions.

In addition, under the second electrode, the first electrode 26 is arranged in a direction crossing the second electrode 30.

The first electrode 26 may be a lower electrode, and the second electrode 30 may be an upper electrode. In the same manner, the first poling electrode 27 may be a lower poling electrode, and the second poling electrode 31 may be an upper poling electrode. The second metal layer may be formed on the first poling electrode 27. The second metal layer arranged on the first poling electrode 27 may be separated by the second electrode 30 and the insulation layer 23.

FIG. 16 is a view showing the configuration of applying poling voltage.

Poling treatment is activating a piezoelectric material by applying high voltage to the piezoelectric material. It is also referred to as a polarization process. If a high voltage is applied to the piezoelectric material, dipoles are arranged in a predetermined direction, and this process is referred to as poling. The dipole refers to arranging two charges having the same size and opposite symbols side by side.

As shown in FIG. 16, a voltage is applied to the first poling electrode 27 and the second poling electrode 31, and since the first poling electrode 27 and the second poling electrode 31 are arranged on the same surface, poling voltage also can be applied with ease. When the poling voltage is applied, the poling process may be performed by dipping the substrate in a silicon oil 32.

At this point, since the first electrode 26 is connected to the first poling electrode 27 and the second electrode 30 is connected to the second poling electrode 31, although voltage is applied only to the first poling electrode and the second poling electrode 31, the voltage may be applied to all the piezoelectric rods 20.

If the poling process is completed, the piezoelectric rod 20 arrays are separated through a dicing process (step S19). Although the piezoelectric rods are separated through the dicing process, an unnecessary dummy substrate 28 is attached to each piezoelectric rod. Since the dummy substrate 28 is bonded using an adhesive material, it can be easily removed if a heat higher than a predetermined temperature is applied.

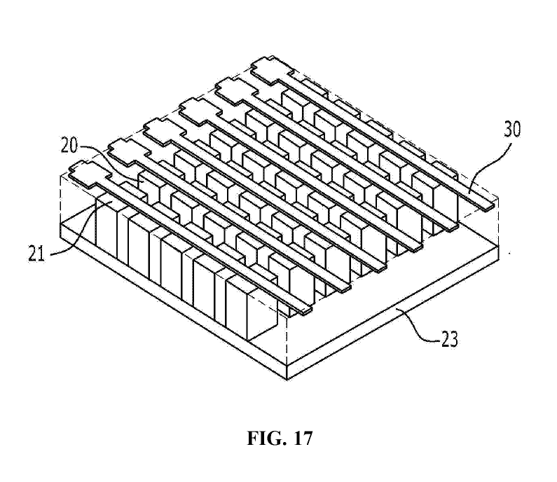

FIG. 17 is a view showing a piezoelectric sensor completed after a dicing process.

Referring to FIG. 17, the first electrode is formed on the insulation layer 26, and the piezoelectric rods 20 and the conductive rods 21 are formed on the first electrode. The first electrode is a lower electrode not shown in the figure. The second electrode 30 is formed on the piezoelectric rods 20 and the conductive rods 21.

Although the first electrode is arranged on the bottom, power can applied from the top since the conductive rods 21 are protruded upward. It may be confirmed that the second electrode 30 is exposed to the outside, and the piezoelectric material 18 is separated by the insulation material 23.

An ultrasonic piezoelectric sensor can be manufactured through the process as described above, and since both the first electrode and the second electrode are exposed in the same direction in the piezoelectric sensor manufactured in the method as described above, a wire bonding work is much easier than a conventional work.

Of course, although there is a step between the first electrode and the second electrode to some extent as shown in FIG. 17, since the step is ignorable in reality, it does not make a problem in doing a wiring work.

According to the present invention, both the upper electrode and the lower electrode of the piezoelectric sensor may be exposed on the same surface. Therefore, voltage can be applied more easily, and the manufacturing process can be reduced.

In addition, according to the present invention, both the upper poling electrode and the lower poling electrode may be exposed on the same surface. Therefore, the poling work can be performed more easily.

Although the preferred embodiments and application examples of the present invention have been described with reference to the drawings, the present invention is not limited to the specific embodiments and application examples described above. It is apparent that diverse modified embodiments can be made by those skilled in the art without departing from the scope and spirit of the present invention, and the modified embodiments should not be understood to be distinguished from the spirits and prospects of the present invention.

What is claimed is:

1. A piezoelectric sensor manufacturing method comprising the steps of:
forming a mold in a form of a sensor array pattern including a plurality of grooves by etching a base substrate;
injecting a piezoelectric material in inner grooves among the plurality of grooves and injecting a conductive material in outer grooves;
sintering the injected piezoelectric material and the conductive material;
forming piezoelectric rods and conductive rods by etching the base substrate to protrude the piezoelectric material and the conductive material;
forming an insulation layer by filling an insulation material in the base substrate;
flattening the insulation layer until the piezoelectric rods and the conductive rods are exposed;
forming a first electrode on a first surface of the piezoelectric material and the conductive material;
bonding a dummy substrate on the base substrate on which the first electrode is formed;
flattening the base substrate until the piezoelectric rods and the conductive rods are exposed; and
forming a second electrode on a second surface of the piezoelectric rods and the conductive rods.

2. The method according to claim 1, wherein the step of forming a mold in a form of a sensor array pattern including a plurality of grooves by etching a base substrate includes the step of further forming a hole for forming a poling electrode in a predetermined area of the base substrate.

3. The method according to claim 2, wherein the step of injecting a piezoelectric material in inner grooves among the plurality of grooves and injecting a conductive material in outer grooves includes the step of injecting a conductive material for poling in the hole for forming a poling electrode.

4. The method according to claim 1, wherein the step of forming a first electrode includes the steps of:
depositing a metal layer on the piezoelectric rods and the conductive rods;
applying photoresist on the metal layer;
removing part of the photoresist by exposing to light according to a mask pattern;
etching the metal layer of the part from which the photoresist is removed; and
removing remaining photoresist after etching the metal layer.

5. The method according to claim 3, wherein the step of forming a first electrode includes the step of forming a first poling electrode by depositing a metal layer on the conductive material for poling and connecting the first poling electrode and the first electrode in one piece.

6. The method according to claim 2, wherein the step of forming a second electrode includes the step of forming a second poling electrode in a predetermined area of a second surface of the insulation layer.

7. The method according to claim 6, wherein the second electrode is formed to be connected to the second poling electrode in one piece.

8. The method according to claim 1, wherein the second electrode is formed to separate the metal layer formed on the piezoelectric rods and the metal layer formed on the conductive rods.

9. The method according to claim 6, further comprising a poling step of activating the piezoelectric material by applying poling voltage to the first electrode and the second electrode.

10. The method according to claim 1, wherein the second electrode is formed to cross the first electrode in a perpendicular direction.

11. The method according to claim 1, wherein the step of forming a second electrode includes the steps of:
depositing a metal layer on the piezoelectric rods and the conductive rods;
applying photoresist on the metal layer;
removing part of the photoresist by exposing to light according to a mask pattern;
etching the metal layer of the part from which the photoresist is removed; and
removing remaining photoresist after etching the metal layer.

12. The method according to claim 1, wherein the step of forming grooves includes the steps of:
forming a pattern of a sensor array form on a first surface of the base substrate through a photolithography process;
removing the photoresist formed on the base substrate and depositing an insulation layer; and
forming the grooves at regular intervals on the base substrate by etching the area from which the photoresist is removed.

13. The method according to claim 1, wherein in the sintering step, the injected piezoelectric material and conductive material are sintered at a low temperature for a first period and sintered at a high temperature for a second period.

14. The method according to claim 13, wherein the low temperature is 450 to 550° C.

15. The method according to claim 11, wherein the high temperature is 1050 to 1300° C.

16. The method according to claim 1, wherein the conductive material includes any one of a carbon composite, a chopped carbon fiber, an isotropic graphite material, a polyimide composite material power and a rayon-based carbon fiber.

17. A piezoelectric sensor comprising:
a lower electrode;
piezoelectric rods formed on the lower electrode;
conductive rods formed at one side of the piezoelectric rod; and
an upper electrode arranged to cross the lower electrode formed on the piezoelectric rods, wherein
power is applied to the lower electrode through the conductive rods.
